(19) United States
(12) Patent Application Publication
(10) Pub. No.: US 2024/0402302 A1
(43) Pub. Date: Dec. 5, 2024

(54) TOF MODULE LEVERAGING FOPLP TECHNOLOGY

(71) Applicant: II-VI Delaware, Inc., Wilmington, DE (US)

(72) Inventors: Francesco Schiattone, Wilmington, DE (US); Jason O’Daniel, Wilmington, DE (US); Pei-Song Cai, Wilmington, DE (US); Hong-Zhi Liu, Wilmington, DE (US); Yi-Yung Chen, Wilmington, DE (US)

(21) Appl. No.: 18/677,294

(22) Filed: May 29, 2024

Related U.S. Application Data
(60) Provisional application No. 63/505,280, filed on May 31, 2023.

(51) Int. Cl. G01S 7/481; H01S 5/02253; H01S 5/42

(52) U.S. Cl. CPC G01S 7/4813; H01S 5/02253; H01S 5/423

(57) ABSTRACT

This disclosure describes a Time of Flight (ToF) device leveraging semiconductor Fan-Out Panel Level Packaging (FOPLP) technology. The ToF device comprises a laser, a transmit optical assembly (TxO), a receive optical assembly (RxO), and a time of flight (ToF) sensor. The laser and the ToF sensor are embedded in a first compound. The TxO and the RxO are embedded in second compound that is different than the first compound.

### CROSS REFERENCE TO RELATED APPLICATIONS

This application claims the benefit of and priority to U.S. Provisional Patent Application No. 63/505,280, titled “TOF MODULE LEVERAGING FOPLP TECHNOLOGY,” filed May 31, 2023, the disclosure of which is incorporated herein by reference in its entirety.

### BACKGROUND

Limitations and disadvantages of traditional Time of Flight (ToF) modules will become apparent to one of skill in the art, through comparison of such approaches with some aspects of the present method and system set forth in the remainder of this disclosure with reference to the drawings.

### BRIEF SUMMARY

Systems and methods are provided for a Time of Flight (ToF) module leveraging semiconductor Fan-Out Panel Level Packaging (FOPLP) technology, substantially as illustrated by and/or described in connection with at least one of the figures, as set forth more completely in the claims.

### BRIEF DESCRIPTION OF THE DRAWINGS

FIG. 1 illustrates an example of a ToF module in accordance with various example implementations of this disclosure.

### DETAILED DESCRIPTION

This disclosure describes a system and method for 3D sensing and/or targeting. Such 3D sensing/targeting may be embodied in a module that may be incorporated into a wide range of consumer devices. For example, a mobile phone may use the module for enabling augment reality (AR) and/or virtual reality (VR) applications. This disclosure provides a solution for achieving an ultra-compact module footprint. For example, the footprint size may be reduced by 50%.

The module may comprise a transmitter and a receiver. The transmitter may comprise one or more Addressable Vertical Cavity Surface Emitting Lasers (VCSELs) and one or more transmit optical lenses. Multiple VCSELs may be separated and differentiated in space, time and/or frequency. The receiver may comprise a Time of Flight (ToF) sensor and one or more receive optical lenses. The module may leverage semiconductor Fan-Out Panel Level Packaging (FOPLP) technology.

An FOPLP module, in accordance with various example implementations of this disclosure, may comprise connections fanned-out of the chip surface, enabling more external I/Os. An epoxy mold compound may be used to fully embed dies, rather than placing the dies upon a substrate or interposer. The FOPLP module may comprise dicing chips on a silicon wafer. The chips may be positioned on a thin reconstituted or carrier wafer/panel, which is then molded and followed by a redistribution layer (RDL) atop the molded area (chip and fan-out area). Solder balls may be located on top of the RDL.

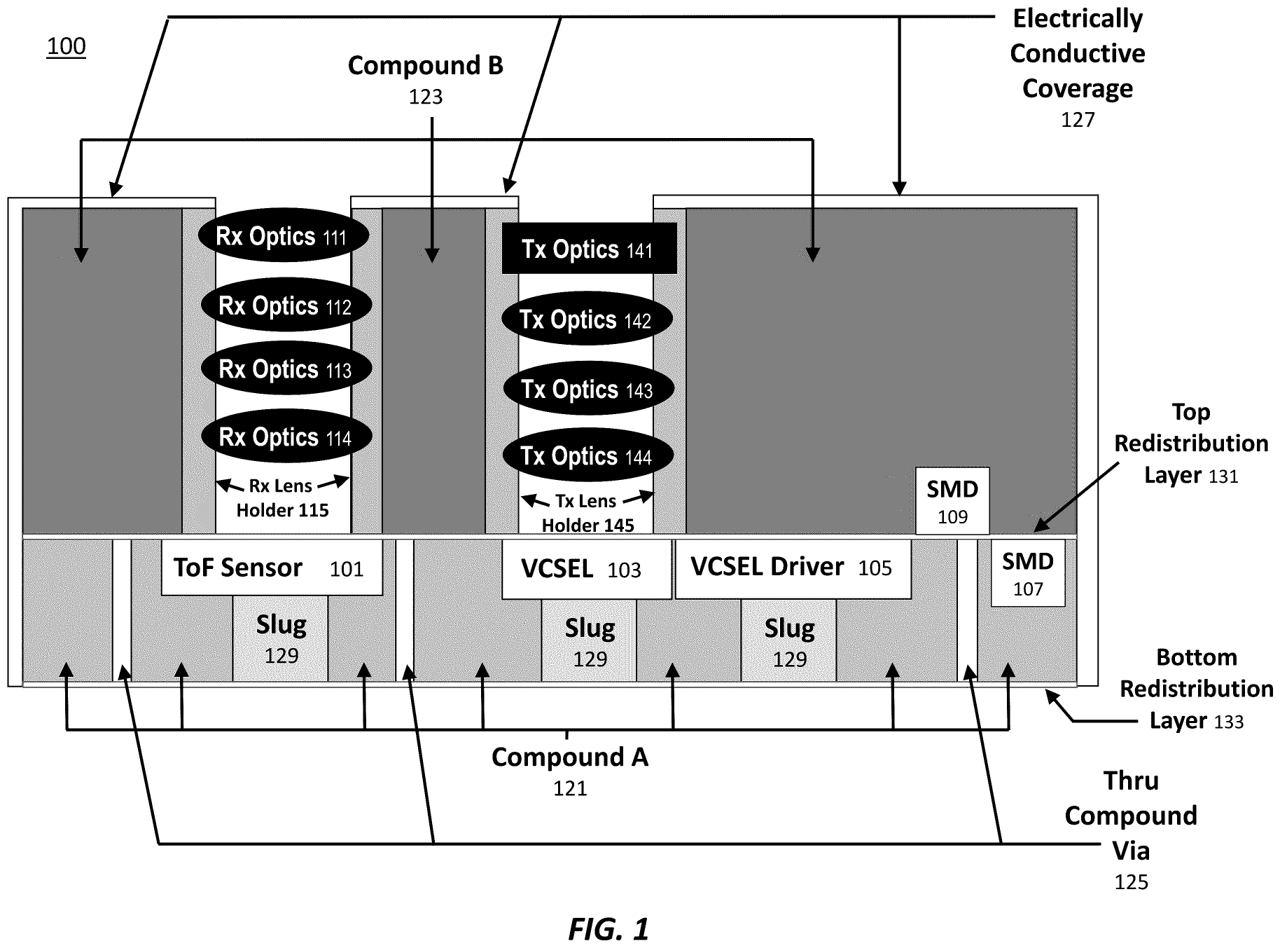

FIG. 1 illustrates an example of a ToF module in accordance with various example implementations of this disclosure.

The ToF module in FIG. 1 comprises a ToF sensor chip 101, a VCSEL 103, a VCSEL driver 105 and surface mount devices (SMDs) 107. The SMDs may comprise passive components, such as capacitors, resistors and inductors. The ToF sensor chip 101, the VCSEL 103, the VCSEL driver 105 and the SMDs 107 are embedded in epoxy molding compound A (EMC A). The EMC A is located between a top RDL and a bottom RDL. Several vias are configured between the top RDL and the bottom RDL. Vias may connect to VCSEL 103, ToF sensor 101, VCSEL driver 105 and/or other components as necessary.

The ToF module in FIG. 1 is not surface mounted and does not require a substrate, solder printing, surface mounting, reflow, die bonding, wire bonding, housing, laser direct structuring (LDS) or metal cans. The ToF module in FIG. 1 allows multiple components to be positioned densely, simplifies the process step, lowers cost and reduces the module footprint by up to 50%.

The ToF sensor chip 101, the VCSEL 103, the VCSEL driver 105 and the SMDs 107 of FIG. 1 are bonded or soldered on (or above) a substrate. A module size that is thinner than conventional ToF modules is achievable.

Metal and/or ceramic slugs may be located under the ToF sensor chip 101, the VCSEL 103, the VCSEL driver 105 and the SMDs 107 to dissipate heat power that may be generated. Slugs 129 (comprising, for example, aluminum nitride (AIN), copper and/or sintering silver) may have a thermal conductivity above 100 W/m K. Slugs 129 have better thermal conductivity than conventional High Temperature Co-Fired Ceramic (HTCC) substrate PCB with multi layers.

Optionally, several O/E components may be located above the top RDL. For example SMD, VCSELs, PMIC and other components may be embedded in EMC B 123. Some components (originally embedded inside EMC A 121) may be soldered/bonded on the top RDL for further reducing the module size. For example, some capacitors may be embedded in EMC A 121 and some capacitors may be located above the EMC A 121, thereby allowing a smaller possible footprint.

Transmit optics are located above the VCSEL 103 for generating far-field (FF) illumination, dot illumination or flood illumination based on refractive and/or diffractive principles. The transmit lenses are fixed via holders to ensure that the optics are positioned on the right location relative to tip/tilt/rotation/z/x/y etc. The lens holder may be made of metal, ceramic and/or organic materials. The lens holder and the optics may be made of the same material to produce optics with an integrated holder. One of more lenses may be used. Both active alignment and passive alignment may be used.

Receive optics are located above the ToF Sensor 101 for imaging on sensor's pixel area. As with the transmit section, the receive lens holder may be made of metal, ceramic and/or organic materials. The lens holder and the optics may be made of the same material to produce optics with an integrated holder. One of more lenses may be used. Both active alignment and passive alignment may be used.

Conductive film may cover the EMC B 123 area except for the transmit and receive optical sections. The conductive film may provide EMI shielding for eye safety. The conductive film may also create a metal trace on the EMC B 123 functions. The conductive film may be made by spray coating, electro plating and/or deposition.

In an alternate configuration, the EMC A 121 and the EMC B 123 may be replaced by one or more alternate materials, such as a silicone compound. For the EMC B area, the material may be placed via a dispensing process rather than a molding process, such as transfer molding or compression molding.

At least one surface of the ToF sensor chip 101, the VCSEL 103 and the VCSEL driver 105 may be on the same level. SMDs may be arranged inside the EMC A 121 and the EMC B 123. Ceramic slugs (electrically isolated) or metal slugs 129 (electrically conductive) may be located directly under the VCSEL 103 and the VCSEL driver 105.

The ToF device 100, comprises a laser 103, a transmit optical assembly (TxO) 141-145, a receive optical assembly (RxO) 111-115 and a ToF sensor 101. The laser 103 and the ToF sensor 101 are embedded in a first compound 121 (e.g., EMC A). The TxO 141-145 and the RxO 111-115 are embedded in second compound 123 (e.g., EMC B) that may be different than the first compound.

The laser 103 may comprise a VCSEL or a plurality of addressable VCSELs. The TxO 141-145 comprises one or more lens 141-144 and a lens holder 145. The one or more lens 141-144 and the lens holder 145 may be integrated together and may be made of the same material. The RxO 111-115 comprises one or more lens 111-114 and a lens holder 115. The one or more lens 111-114 and the lens holder 115 may be integrated together and may be made of the same material. The laser 103, in combination with the TxO 141-145, may generate a full-field illumination, a dot illumination and/or a flood illumination. The TxO and/or the RxO may be actively aligned.

The compound A 121 and the compound B 123 may be different types of an epoxy mold compound (EMC) or different types of a silicone compound. The compound B 123 may be covered by a conductive film 127. The conductive film 127 may comprise a metal trace operable to provide eye safety. The ToF device may comprise Fan-Out Panel Level Packaging (FOPLP).

One or more slugs 129 may be coupled between a bottom redistribution layer 133 and one or both of the ToF sensor 101 and the laser 103. The one or more slugs 129 may comprise aluminum nitride, copper and/or sintering silver. A top redistribution layer 131 may be coupled between the compound A 121 (e.g., EMC A) and the compound B 123 (e.g., EMC B). One or more vias 125 may be located between the bottom redistribution layer 133 and the top redistribution layer 131. The bottom redistribution layer 133 and the top redistribution layer 131 may each comprise one or more metal traces. One or more surface mount devices (SMDs) 107, 109 may be operably coupled above or below the top redistribution layer 131. An SMD 107 below the top redistribution layer 131 may be embedded in the compound A 121. An SMD 109 above the top redistribution layer 131 may be embedded in the compound B 123.

As used herein the terms “circuits” and “circuitry” refer to physical electronic components (i.e. hardware) and any software and/or firmware (“code”) which may configure the hardware, be executed by the hardware, and or otherwise be associated with the hardware. As used herein, for example, a particular processor and memory may comprise a first “circuit” when executing a first one or more lines of code and may comprise a second “circuit” when executing a second one or more lines of code. As used herein, “and/or” means any one or more of the items in the list joined by “and/or”. As an example, “x and/or y” means any element of the three-element set {(x), (y), (x, y)}. As another example, “x, y, and/or z” means any element of the seven-element set {(x), (y), (z), (x, y), (x, z), (y, z), (x, y, z)}. As used herein, the term “exemplary” means serving as a non-limiting example, instance, or illustration. As used herein, the terms “e.g.,” and “for example” set off lists of one or more non-limiting examples, instances, or illustrations. As used herein, circuitry is “operable” to perform a function whenever the circuitry comprises the necessary hardware and code (if any is necessary) to perform the function, regardless of whether performance of the function is disabled or not enabled (e.g., by a user-configurable setting, factory trim, etc.). As used herein, the term “based on” means “based at least in part on.” For example, “x based on y” means that “x” is based at least in part on “y” (and may also be based on z, for example).

While the present method and/or system has been described with reference to certain implementations, it will be understood by those skilled in the art that various changes may be made and equivalents may be substituted without departing from the scope of the present method and/or system. In addition, many modifications may be made to adapt a particular situation or material to the teachings of the present disclosure without departing from its scope. Therefore, it is intended that the present method and/or system not be limited to the particular implementations disclosed, but that the present method and/or system will include all implementations falling within the scope of the appended claims.

What is claimed is:

1. A device, comprising:
a laser;
a transmit optical assembly (TxO);
a receive optical assembly (RxO); and
a time of flight (ToF) sensor, wherein:
the laser and the ToF sensor are embedded in a first compound, and
the TxO and the RxO are embedded in a second compound that is different than the first compound.

2. The device of claim 1, wherein the laser comprises a Vertical Cavity Surface Emitting Laser (VCSEL).

3. The device of claim 1, wherein the laser comprises a plurality of addressable VCSELs.

4. The device of claim 1, wherein the TxO comprises one or more lens and a lens holder.

5. The device of claim 4, wherein the one or more lens and the lens holder are integrated and made of a same material.

6. The device of claim 1, wherein the RxO comprises one or more lens and a lens holder.

7. The device of claim 6, wherein the one or more lens and the lens holder are integrated and made of a same material.

8. The device of claim 1, wherein the laser, in combination with the TxO, is operable to generate one or more of a full-field illumination, a dot illumination and a flood illumination.

9. The device of claim 1, wherein one or both of the TxO and the RxO are actively aligned.

10. The device of claim 1, wherein one or both of the first compound and the second compound comprise an epoxy mold compound (EMC).

11. The device of claim 1, wherein one or both of the first compound and the second compound comprise a silicone compound.

12. The device of claim 1, wherein the compound B is covered by a conductive film.

13. The device of claim 12, wherein the compound B comprises a metal trace operable to provide eye safety.

14. The device of claim 1, wherein the device comprises Fan-Out Panel Level Packaging (FOPLP).

15. The device of claim 1, wherein one or more slugs are operably coupled between a bottom redistribution layer and one or both of the ToF sensor and the laser.

16. The device of claim 15, wherein the one or more slugs comprise aluminum nitride, copper and/or sintering silver.

17. The device of claim 1, wherein a top redistribution layer is operably coupled between the compound A and the compound B.

18. The device of claim 17, wherein one or more vias are located between a bottom redistribution layer and the top redistribution layer.

19. The device of claim 17, wherein the top redistribution layer comprises one or more metal traces.

20. The device of claim 17, wherein:
one or more surface mount devices (SMDs) are operably coupled above or below the top redistribution layer,
an SMD below the top redistribution layer is embedded in the compound A, and
an SMD above the top redistribution layer is embedded in the compound B.
